(19) United States
(12) Patent Application Publication
(10) Pub. No.: US 2005/0284372 A1
(43) Pub. Date: Dec. 29, 2005

(54) Chamber component having grooved surface with depressions

(75) Inventors: Laxman Murugesh, San Ramon, CA (US); Abhijit Desai, Fremont, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 10/990,100

(22) Filed: Nov. 16, 2004

Related U.S. Application Data
(63) Continuation-in-part of application No. 10/880,235, filed on Jun. 28, 2004.

(51) Int. Cl. C23C 16/00

(52) U.S. Cl. 118/715; 430/942

(57) ABSTRACT

A substrate processing chamber component is capable of being exposed to an energized gas in a process chamber. The component has an underlying component structure and a surface on the underlying structure. The surface has a plurality of concentric grooves that are radially spaced apart across the surface, and electron beam textured depressions formed between adjacent grooves on the surface. The process residues adhere to the surface to reduce the contamination of processed substrates.

### CROSS-REFERENCE

This application is a continuation-in-part of U.S. patent application Ser. No. 10,880,235, entitled “Chamber Component Having Knurled Surface” to Tsai et al, assigned to Applied Materials, Inc. and filed on Jun. 28, 2004, which is herein incorporated by reference in its entirety.

### BACKGROUND

Embodiments of the present invention relate to components for a substrate processing chamber.

In the processing of substrates, such as semiconductor wafers and displays, a substrate is placed in a process chamber and exposed to an energized gas to deposit or etch material on the substrate. A typical process chamber comprises process components including an enclosure wall that encloses a process zone, a gas supply to provide a gas in the chamber, a gas energizer to energize the process gas to process the substrate, a substrate support, and a gas exhaust. The process chamber components can also comprise a process kit, which typically includes one or more parts that can assist in securing and protecting the substrate during processing. An example of a process kit component is a retaining clamp, which can at least partially encircle a periphery of a substrate to secure the substrate on the support. The retaining clamp can also at least partially cover one or more of the substrate and support to reduce the deposition of process residues thereon.

During processing of a substrate in a process chamber, process residues are generated that can deposit on internal surfaces in the chamber. For example, process residues can deposit on surfaces including a surface of the retaining clamp, a substrate support surface, and surfaces of enclosure walls. In subsequent process cycles, the deposited process residues can “flake off” of the internal chamber surfaces to fall upon and contaminate the substrate. To solve this problem, the surfaces of components in the chamber are often textured to reduce the contamination of the substrates by process residues. Process residues adhere to these textured surfaces, and the incidence of contamination of the substrates by the process residues is reduced.

In one version, a textured component surface is formed by directing an electromagnetic energy beam onto a component surface to form depressions and protrusions to which the process deposits can better adhere. The textured component surface can also be provided by forming a textured coating on a component. However, even such textured component surfaces may not sufficiently solve process residue build-up problems. In particular, excessive accumulation of process residues on textured component surfaces that are near the substrate receiving area of the substrate support can result in flaking of the accumulated residues from these surfaces, which may include surfaces of the retaining clamp or the substrate receiving surface. As the dimensions of the components around the substrate receiving region are typically carefully selected to provide a close fit to the substrate, the build-up of process residues in this region can result in an improper fit of the substrate on the support, or even “sticking” of substrate to one or more of the receiving surface and clamp ring. Substrate sticking is especially problematic, for example, in high temperature processes such as aluminum re-flow processes, in which aluminum-containing material and other process residues soften and flow on heated surfaces within the chamber.

Yet another problem arises when relatively small or narrow textured features on the textured components, such as holes or depressions in the component surface, fill-up with process residues too quickly, requiring cleaning of the component after processing of only a few substrates. Also, a film of process residue can “bridge” or stop up holes or depressions in the textured component surface, limiting the amount of process residues that can accumulate on the component surface without flaking off. The “bridged” film may also not be as firmly held on the textured surface causing premature spalling from the surface. Thus, conventional textured surface components often do not allow a sufficiently large number of substrates to be processed before cleaning of the component is required, thereby reducing processing efficiency and increasing chamber downtime. The conventional components can even contaminate substrates with loosely held residues that spall off from the component surfaces.

Accordingly, it is desirable to reduce flaking of accumulated process residues from components located near the substrate receiving area. It is further desirable to prevent “sticking” of substrates to portions of a substrate support. It is furthermore desirable to allow increased amounts of process residue accumulation on component surfaces, with reduced bridging of holes or depressions on the component surface.

### SUMMARY

A substrate processing chamber component that is capable of being exposed to an energized gas in a process chamber, has an underlying component structure and a surface with a plurality of concentric grooves that are radially spaced apart across the surface, and electron beam textured depressions formed between adjacent grooves on the surface. Process residues adhere better to the surface to reduce the contamination of processed substrates.

The component can be manufactured by machining a plurality of concentric grooves into the surface of a component structure, the concentric grooves being radially spaced apart on the surface. An electron beam is scanned across the surface to form a plurality of electron beam textured depressions between adjacent concentric grooves.

### DRAWINGS

These features, aspects, and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1a is a top view of an embodiment of a retaining clamp having a knurled surface;

FIG. 1b is a sectional side view of an embodiment of a retaining clamp having a knurled surface;

FIG. 2a is a plan view of an embodiment of a knurling tool having hardened edges;

FIG. 2b is a sectional side view of an embodiment of the hardened edges of the knurling tool of FIG. 2b;

FIG. 3 is a sectional side view of an embodiment of a sputtering chamber having a component with a textured surface;

FIG. 4 is a sectional side view of an embodiment of a component having a textured surface with a plurality of electron beam textured depressions between concentric grooves; and

FIG. 5 is a sectional side view of an embodiment of an electron beam textured depression formed in a surface of a component.

### DESCRIPTION

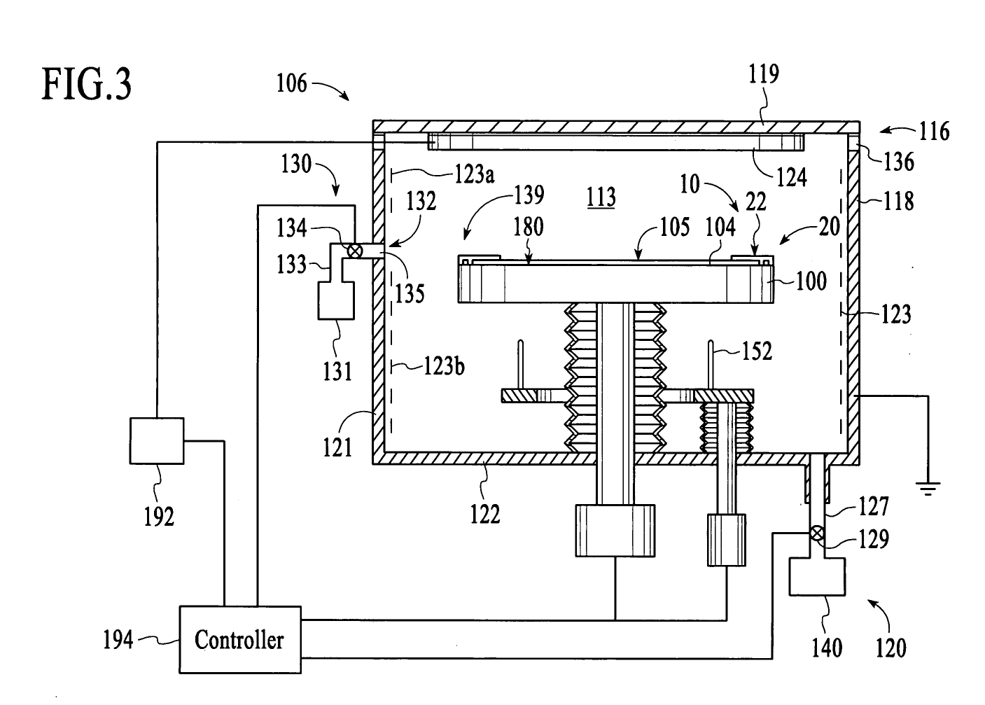

A substrate processing chamber 106 (shown in FIG. 3) comprises components 10 for processing a substrate 104 in an energized gas. One or more of the components 10 can comprise a component structure 11 that has a surface 22 that is textured, such that process residues generated during the processing of substrates 104 can adhere to the component surface 22 to reduce the contamination of processed substrates 104 from the process residues. The components 10 having the textured surface 22 can include, for example, a portion of a gas supply 130 that provides process gas in the chamber 106, such as a gas distributor 132, a portion of a substrate support 100 that supports the substrate 104 in the chamber 106, a process kit 139, including for example one or more of a retaining clamp 20, cover ring, and deposition ring, an insulator ring 136, a gas energizer 116 that energizes the process gas, one or more chamber enclosure walls 118, one or more shields 123, such as upper and lower shields 123a,b and a gas exhaust 120 that exhausts gas from the chamber 106.

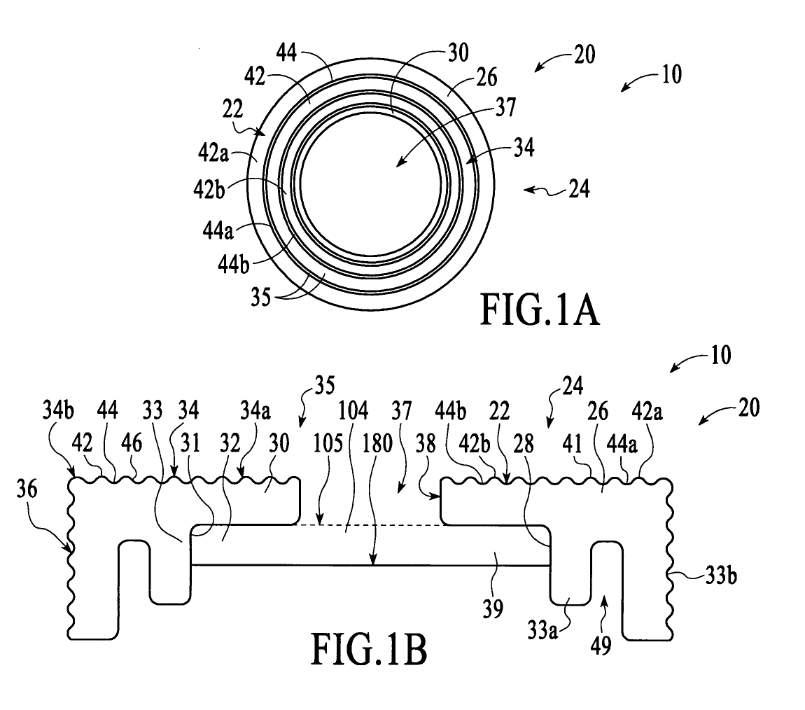

In one version, the component 10 comprises a substrate retaining clamp 20 having a surface 22 that is textured to reduce the contamination of substrates 104 by process residues, as shown for example in FIGS. 1a and 1b. The substrate retaining clamp 20 is capable of securing a substrate 104 onto a substrate receiving surface 180 of a substrate support 100, and may also be capable of reducing the deposition of process residues onto the substrate 104.

In the version shown in FIGS. 1a and 1b, the substrate retaining clamp 20 comprises a ring 24 that has an annular outer portion 26 about the substrate 104, and an overhang ledge 30 that extends at least partially over a periphery of the substrate 104. A top surface 105 of the substrate 104 is exposed through a substantially circular opening 37 in the ring 24. The annular outer portion 26 of the ring 24 comprises an inner wall 33 having a diameter 31 that is sufficiently large to at least partially surround a perimeter 28 of a substrate 104 positioned on the support 100, thereby at least partially securing the substrate 104 on the support 100. The overhang ledge 30 extends inwardly from the annular outer portion 26 to at least partially cover a periphery 39 of the substrate 104, and can extend from about 1 millimeter to about 1.5 millimeters over the periphery 39 of the substrate 104 and even seat on the periphery 39 of the substrate 104. In the version shown in FIGS. 1a and 1b, a top surface 34 of the retaining clamp 20 faces a process zone 113 in the chamber 106 and extends across both the overhang ledge 30 and annular portion 26 of the retaining clamp 20. The top surface 34 may be substantially parallel to a top surface 105 of the substrate 104. The overhang ledge 30 can protect the peripheral portion of the substrate 104 from the re-deposition of process residues onto the substrate 104, and can also hold or “clamp” the substrate 104 to secure the substrate 104 to a substrate receiving surface 180 of the support 100 during processing.

The retaining clamp 20 can comprise further structural elements to connect the retaining clamp 20 to a portion of the process chamber 106. For example, as shown in FIG. 1b, the retaining clamp 20 can comprise one or more downwardly extending walls 33a,b. A first downwardly extending wall 33a can comprise a first annular wall having an inner diameter 31 that surrounds and is adjacent to the outer perimeter 28 of the substrate 104, to protect the sides of the substrate 104. The overhang ledge 30 may extend radially inwardly from the first downwardly extending wall 33a. A second downwardly extending wall 33b can comprise a second annular wall that is concentrically exterior to the first downwardly extending wall 33a, with a connecting space 49 remaining between the first and second walls 33a,b. The connecting space 49 may be capable of accommodating a portion of the support 100 to connect the retaining clamp 20 to the support 100, as shown for example in FIG. 3. The second downwardly extending wall 33b can also extend downwardly a sufficient distance to at least partially cover and inhibit erosion of interior parts of the substrate support 100.

It has been discovered that improved processing results are provided by forming a textured surface 22 comprising a knurled exposed surface 22 on at least a portion of the retaining clamp. The knurled exposed surface 22 can be formed by pressing one or more hardened edges 56 into a surface of the retaining clamp 20, for example by rolling the hardened edges over the surface, thereby imprinting or embossing a pattern of features 35 onto the surface. The pattern of features 35 can comprise depressions and projections on the knurled exposed surface 22. In the examples shown in FIGS. 1a and 1b, the features 35 comprise a plurality of projections and depressions in the knurled exposed surface 22 that comprise raised ridges 42 as well as depressed furrows 44 or channels. The raised ridges 42 and depressed furrows 44 comprise amplitudes about a centerline 46 representing a median height of the knurled exposed surface 22 that improves the adhesion of residues to the knurled exposed surface 22. The amplitudes of the ridges 42 and furrows 44 comprise the maximum departure of the ridge height or furrow depth from the centerline or average surface height. In one version, one or more of the ridges 42 comprise an amplitude above the centerline 46 that is at least about 0.5 millimeters and less than about 2.5 millimeters, such as from about 1 millimeter to about 1.5 millimeters. The furrows 44 comprise channels or trenches in the knurled exposed surface 22 that extend below the centerline 46 to provide depressions in the knurled exposed surface 22. For example, one or more of the furrows can comprise an amplitude below the centerline 46 of at least about 0.5 millimeters and less than about 2.5 millimeters, such as from about 1 millimeter to about 1.5 millimeters.

The number of knurled ridges 42 and furrows 44 provided by the pattern of features 35 is also selected to provide optimized adhesion of the residues. For example, the retaining clamp 20 can comprise from about 100 to about 150 ridges 42 and about 100 to about 150 furrows 44. The knurled exposed surface 22 having the ridges 42 and furrows 44 provides improved substrate processing performance by providing features 35 capable of collecting process residues to reduce substrate contamination and “sticking” of the substrate 104 to the support 100.

The knurled exposed surface 22 can be provided on portions of the retaining clamp 20 that improve the adhesion of process residues, such as on surfaces that are exposed to energized gases in the chamber 106. In one version, the knurled exposed surface 22 comprises at least a portion of an exposed surface of the overhang ledge 30. Providing the knurled exposed surface 22 on the overhang ledge 30 reduces the amount of residue that can collect in the substrate receiving area to reduce contamination and sticking of the substrate 104. For example, the knurled exposed surface 22 can comprise at least a portion of and even substantially an entire top surface 34a of the overhang ledge 30 to reduce the flow of residues towards the substrate 104. The knurled exposed surface can also or alternatively comprise at least a portion of a top surface 34b of the outer annular portion 26. In one version, the knurled exposed surface 22 extends across substantially the entire top surface 34 of the retaining clamp 20, as shown for example in FIGS. 1a and 1b.

The knurled exposed surface 22 can also comprise at least a portion of another surface of the retaining clamp 20, such as at least a portion of an exterior side surface 36 of the clamp 20. The exterior side surface 36 extends downwardly over the second outer sidewall 33b, and may be substantially perpendicular to the top surface 34 of the retaining clamp 20. In one version, the retaining clamp 20 comprises a substantially continuously knurled exposed surface 22 that extends across the top surface 34 and down at least a portion of the outer side surface 36, as shown for example in FIG. 1b. Other portions of the clamp 20 can also comprise the knurled exposed surface 22, such as for example the interior side surface 38 of the overhang ledge 30.

In one version, the knurled exposed surface 22 comprises ridges 42 and furrows 44 that are arranged concentrically with respect to one another. For example, the knurled exposed surface 22 may comprise a radial pattern of ridges 42 and furrows 44 on at least a portion of the top surface 34 that encircle the central opening 37 in the retaining clamp 20, and may even be substantially coaxial with the central opening 37, as shown for example in FIG. 1a. The ridges 42 and furrows 44 encircling the central opening 37 increase in circumference with increasing radius of the retaining clamp 20, such that interior ridges 42a and furrows 44a that are closer to the central opening 37 are nested concentrically inside exterior ridges 42b and furrows 44b that are towards the periphery of the retaining clamp 20. The ridges 42 and furrows 44 are preferably substantially circular and can form rings about the central opening 37 on the surface 22. The ridges 42 and furrows 44 may also comprise other concentric shapes, such as concentric ovals, or other elliptical shapes. The ridges 42 and furrows 44 can also alternate radially along the knurled exposed surface 22, to provide a plurality of features 35 to which process residues can adhere, as shown for example in FIG. 1a.

The retaining clamp 20 comprising the knurled exposed surface 22 having the concentric ridges 42 and furrows 44 provides an advantage over other surfaces, because the knurled exposed surface 22 is especially suited to reduce the flow of process deposits towards the substrate 104. For example, in high temperature processes that can re-circulate and re-flow deposits about the chamber 106, the concentric pattern of ridges 42 and furrows 44 reduces the flow of deposits towards the substrate 104. The concentric furrows 44 act as a trap or a moat to catch process residues being re-circulated towards the substrate 104, and the concentric ridges 42 act as barriers to block the progress of residues flowing towards the substrate 104. The circular symmetry of the ridges 42 and furrows 44 provides optimized inhibition of the progress of these residues by blocking a radial flow path of residues that is directed towards the substrate 104.

The ridges 42 and furrows 44 can be radially spaced apart along the knurled exposed surface 22 to provide a desired distance between the ridges 42 and furrows 44. In one version, the ridges 42 and furrows 44 are periodically spaced apart from one another to provide a regularly spaced pattern of features 35. For example, the ridges 42 can comprise peaks 41 corresponding to the tallest point on each ridge 42, and the ridges and furrows 44 can be periodically spaced apart to provide a peak-to-peak distance between adjacent ridges 42 of at least about 0.5 millimeters and less than about 2.5 millimeters, such as at least about 1 millimeter and less than about 1.5 millimeters, with furrows 44 separating the adjacent ridges 42, as shown in FIGS. 1a and 1b. Alternatively, the distance or period between adjacent ridges 42 can be varied with increasing radius of the retaining clamp 20.

In a method of fabricating the retaining clamp 20 comprising the knurled surface 22, a retaining clamp 20 comprising the desired shape is formed. The desired shape of the retaining clamp 20 can be formed by a shaping method such as for example a computer numeric control method (CNC). In this method, the desired shape is provided by using a computer controlled cutting device that is capable of cutting a metal preform in response to control signals from a computer controller. The computer controller comprises program code to direct the cutting device to cut away portions of the preform to leave the desired clamp shape, such as a retaining clamp 20 having a ring comprising an annular portion 26 having a diameter 31 sufficiently large to surround a substrate 104, and an overhang ledge 30 adapted to seat on the substrate 104. Other methods of fabricating a retaining clamp 20 comprising the desired shape can also be used, such as for example casting, drop-forging, stamping, and other methods that are known to one of ordinary skill in the art. Metals suitable for fabricating the retaining clamp 20 can comprise, for example, at least one of stainless steel, aluminum, titanium, and copper. In one version, the retaining clamp is composed of stainless steel.

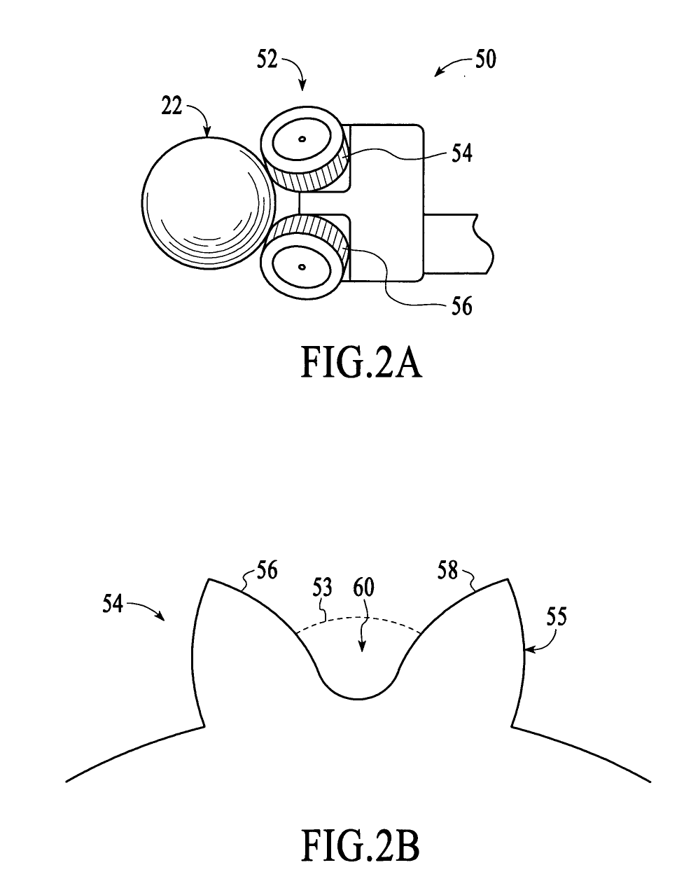

Once the retaining clamp 20 having the desired bulk shape has been formed, the knurling process is performed to form the knurled exposed surface 22 on at least a portion of the clamp 20, such as on the overhang ledge 30. A knurling tool 50 comprising hardened edges 56 is provided to form the knurled features 35 on the clamp 20, as shown for example in FIGS. 2a and 2b. The hardened edges 56 of the knurling tool 50 are formed of a hard material and comprise a shape that is capable of indenting the surface of the retaining clamp 20. In one version, the knurling tool 50 comprises a knurling head 52 having the hardened edges 56 on wheels 54 that can be run across a surface of the retaining clamp 20. The hardened edges 56 comprise a plurality of teeth 58 that press and indent into the surface 22 as they are drawn across the surface 22. The regions where the teeth 58 are pressed into the surface 22 form indentations that correspond to the furrows 44. The ridges 42 in the surface 22 correspond to the gaps 60 between the teeth 58, as shown for example in FIG. 2b. Accordingly, the teeth 58 desirably comprise amplitudes from a centerline 53 representing a median height of a surface 55 of the knurling wheel 54 that is sufficiently large to form furrows 42 and ridges 44 having the desired amplitudes, and also comprise a distance between teeth that is suitable to provide the desired peak-to-peak distance between the ridges 42. A suitable amplitude of the teeth may be from about 0.5 millimeters to about 2.5 millimeters, such as from about 1 millimeter to about 1.5 millimeters, and a suitable peak-to-peak distance may be from about 0.5 millimeters to about 2.5 millimeters, such as from about 1 millimeter to about 1.5 millimeter. In one embodiment of the knurling process, the retaining clamp 20 is secured in a holding device, such as for example a lathe (not shown), while the knurling head 52 is moved across the clamp surface. Alternatively, the surface of the retaining clamp 20 may be moved over the knurling head 52 while the knurling tool 50 is kept still to form the knurled exposed surface 22.

The configuration of the teeth 58 on the knurling head 52 is selected to provide the desired pattern of features 35. For example, in the version shown in FIG. 2a, the knurling head 52 comprises teeth 58 that are perpendicular to a direction of motion of the wheels 54. The knurling head 52 can also comprise teeth 58 that are parallel to the motion of the wheel. The wheels 54 are drawn across the surface 22 of the clamp 20 in a direction such that the teeth 58 are imprinted to form the desired pattern of concentric ridges 42 and furrows 44. For example, a knurling head 52 having a suitable configuration of teeth 58 can be drawn across the surface 22 in a substantially circular path on the surface 22, to provide the concentric ridges 42 and furrows 44. Also, a second pattern of features 35 may be imprinted over the first pattern of features 35 to make a desired surface configuration. For example, a “diamond” patterned knurled surface 22 can be provided by forming a second pattern comprising ridges and furrows that are offset from the first pattern of furrows and ridges. However, a knurled surface 22 having a single pattern consisting essentially of the concentric ridges and furrows may be desirable to provide the optimal blocking of the flow of process deposits towards the substrate 104.

The retaining clamp 20 having the knurled surface 22 can be especially beneficial in high temperature processes such as aluminum re-flow processes that are used to form a layer of aluminum on a substrate 104. An example of an aluminum re-flow process is described in U.S. Pat. No. 6,660,135 to Yu et al, issued on Dec. 9, 2003 and commonly assigned to Applied Materials, which is herein incorporated by reference in its entirety. To form a uniform layer of aluminum on a substrate, one or more initial layers of aluminum can be deposited on a substrate 104 by a physical vapor deposition method in which an energized sputtering gas is provided in a chamber to sputter aluminum material from a target and onto a substrate 104. The substrate 104 having the one or more layers of aluminum is then subjected to a re-flow process to form the more uniform layer of aluminum. In the re-flow process, the substrate 104 having the layer of aluminum is heated to a temperature that is sufficiently high such that the aluminum migrates and re-distributes about the surface 105 of the substrate 104. The re-flowing process typically provides a more uniform layer of aluminum, as the process can fill channels or crevices in the surface 105 of the substrate 104. A typical re-flowing process may involve heating the substrate 104 to a temperature of at least about 250° C., such as from about 250° C. to about 500° C. The improved retaining clamp 20 having the knurled surface 22 inhibits the flow of process residues towards the substrate 104, and also collects loose residue to inhibit deposition of the residues on the substrate 104 or about the substrate receiving area.

The improved retaining clamp 20 having the knurled surface 22 provides improved results over retaining clamps 20 without a knurled surface 22. For example, the improved retaining clamp 20 may allow for at least about 30% more RF watt hours of chamber processing, before cleaning or replacement of the retaining clamp 20 is required. Thus, the improved retaining clamp 20 having the knurled surface 22 allows for the re-flow processing of substantially more substrates 104 than a clamp 20 without the knurled surface 22 before failure of the retaining clamp 20, and thus provides substantially improved process performance over clamps 20 without the knurled surface 22.

After processing a number of substrates 104, the surface 22 of the retaining clamp 20 can be cleaned to remove any process residues, such as aluminum containing residues. In one version, the aluminum-containing residues can be removed by exposing the surface 22 of the clamp 20 to a cleaning solution capable of dissolving or otherwise removing the residues from the surface 22. For example, the surface 22 can be immersed in the cleaning solution, or the cleaning solution can be wiped or sprayed onto the surface 22. The cleaning solution can comprise an acidic solution, such as for example at least one of H₃PO₄, HNO₃ and HF. Other solutions can also be provided alone or in sequence with an acidic solution, such as a basic solution comprising KOH, and optionally solutions comprising H₂O₂.

In one version of a cleaning process, a retaining clamp 20 comprising stainless steel is cleaned to remove aluminum-containing residues by immersing the surface 22 of the clamp 20 in an initial basic cleaning solution comprising about 1 kg of KOH in about 6 liters of de-ionized water. In another version, the surface 22 is immersed in an initial acidic cleaning solution comprising 20 parts by volume of H₃PO₄, 5 parts by volume of HNO₃, and 1 part by volume of de-ionized water, while heating the solution to a temperature of from about 60° C. to about 70° C. In still another version, the surface 22 is immersed in an initial cleaning solution 1 part by weight of KOH, 10 parts by weight of H₂O₂ and 20 parts by weight of de-ionized water. Any of these initial cleaning solutions can be followed by immersion of the surface 22 in one or more subsequent cleaning solutions, such as an acidic cleaning solution comprising 20% by volume HNO₃, 3% by volume HF and the remainder de-ionized water, followed by an acidic solution comprising 50% by volume HNO₃ and 50% by volume of de-ionized water. The cleaning processes are capable of removing aluminum-containing residues substantially without eroding the retaining clamp 20. An example of a cleaning method is described in U.S. patent application Ser. No. 10/304,535, entitled “Method of Cleaning a Coated Process Chamber Component,” to Wang et al, filed on Nov. 25, 2002 and commonly assigned to Applied Materials, Inc. which is herein incorporated by reference in its entirety.

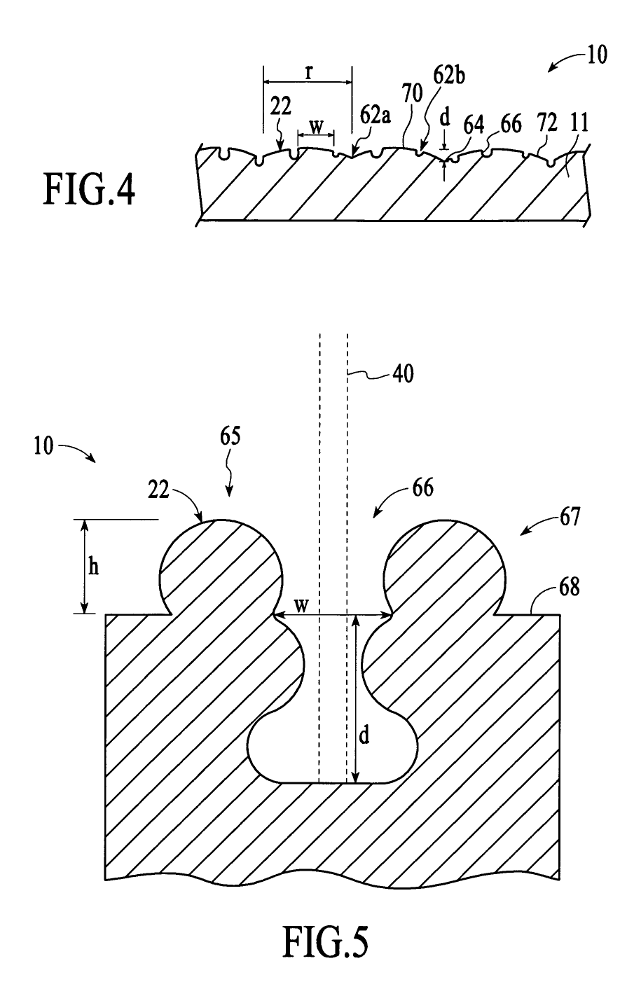

In yet another version, one or more chamber components 10, such as the retaining claim 20, can comprise component structure 11 having a surface 22 with a plurality of surface textures that improve the adhesion of process residues to the surface 22 of the component 10. For example, the surface 22 can comprise first and second surface texture patterns 62a,b, which cooperate to retain process residues on the surface 22 and inhibit the contamination of processed substrates. An example of a component 10 having first and second surface texture patterns 62a,b is shown for example in FIG. 4. In this version, the first surface texture pattern 62a comprises a plurality of concentric grooves 64 that are radially spaced apart across the surface 22 of the component 10. The second surface texture pattern 62b comprises a plurality of textured depressions 66, such as depressions or holes formed by an electron beam textured process, that are formed between adjacent grooves 64 in the surface 22.

In the version shown in FIG. 4, the textured surface 22 allows process residues to accumulate in the electron beam textured depressions 66 on the surface 22 to reduce the contamination of processed substrates 104. The textured surface 22 is further enhanced by the formation of the concentric grooves 64 in the surface 22, which are desirably radially spaced apart across the surface 22 such that a plurality of the depressions 66 are positioned in between adjacent concentric grooves 64. The concentric grooves 64 provide areas for the process deposits to collect, and allow residues to “run-down” into the grooves 64 for collection. Also, the concentric grooves 64 increase the surface area of the component surface 22, allowing for more and wider textured features 35 to be formed on the surface 22, which reduces “bridging” of a deposition film over holes or depressions 66 in the surface 22. The larger surface area of the textured surface 22 also increases the area over which the residues can be adhered. Thus, the surface 22 comprising the concentric grooves 64 and electron beam textured depressions 66 provides improved performance during the processing of substrates 104, and allows for an increased amount of residue to accumulate on the component surface 22 before cleaning of the component 10 is required.

In one version, the textured surface 22 comprises concentric grooves 64 that are relatively deep to enhance the collection and retention of process residues. For example, the grooves 64 may be deeper than those typically formed by a knurling process, and may have a depth d of at least about 3 millimeters, such as from about 3 mm to about 8 mm, and even at least about 4 millimeters, such as from about 4 mm to about 6 mm, and in one version about 5 mm, as measured from the lowest point in the groove 64 to the highest point of a surface region 70 in between grooves 64. The concentric grooves 64 desirably comprise a ring-like shape, such as a circular shape, or even an oval shape. The grooves 64 are concentric about a central axis of the component 10, which may also be a central axis of the process chamber 106.

The spacing of the grooves 64 is selected to provide an optimum number and spacing of depressions 66 therebetween. For example, the grooves 64 may comprise a radial spacing r between adjacent grooves 64 that is selected to be at least twice the width w between adjacent depressions 66, and even at least about three times the width w between adjacent grooves 66. For example, the radial spacing r between adjacent grooves 64 may be at least about 5 millimeters, such as from about 5 millimeters to about 7 millimeters, and even about 6 millimeters, whereas a width w between adjacent depressions 66 may be less than about 3 millimeters, such as from about 1 millimeter to about 3 millimeters, and even about 2 millimeters. The concentric grooves 64 may also be formed in the surface 22 such that surface regions 70 between the grooves 64 comprise a substantially concave surface profile, as shown in FIG. 4. The concave surface profiles of the surface regions 70 gradually taper into the grooves 64 to provide downhill “flow” path for process residues into the grooves 64.

Suitable methods of forming the concentric grooves 64 include machining methods, such as for example utilizing cutting and/or milling tools. For example, the concentric grooves 64 can be cut into the surface 22 of the component structure 11 via a computer numeric control (CNC) machining method. In the CNC method, the desired groove shapes and depths are programmed into a computer controller that controls a cutting device, such as for example a rotating blade, that cuts the grooves 64 into the surface 22. The computer controller comprises program code to direct the cutting device to cut away predetermined volumes of the component surface 22 to form the desired grooves 64 therein. Other methods of forming the desired groove shape can also be used which may be known to those of ordinary skill in the art. The machining method used to form the concentric grooves 64 desirably also forms the concave surface regions 70 between the grooves 64. For example, the cutting tool may comprise one or more angled cutting blades that form gradually sloped groove sidewalls 72. Other milling and cutting methods known to those of ordinary skill in the art may also be used to form the desired grooves, and other metal shaping methods known to those of ordinary skill in the art may also be used, such as for example laser cutting and bending methods.

In one version, the electron beam textured depressions 66 are formed by scanning an electron beam 40 across the surface 22 of the component, to form electron beam textured depressions 66 on the surface 22, as shown for example in FIG. 5. An example of such textured depressions 66 may be formed by a Lavacoat™ process, as described for example in U.S. patent application Ser. No. 10/653,713 to West, et al, filed on Sep. 2, 2004, entitled “Fabricating and Cleaning Chamber Components Having Textured Surfaces,” U.S. patent application Ser. No. 10/099,307, filed Mar. 13, 2002, to Popiolkowski et al, published on Sep. 18, 2003 as U.S. Patent Application Publication No. 2003/0173526, and U.S. patent application Ser. No. 10/622,178, filed on Jul. 17, 2003 to Popiolkowski et al, published on Mar. 25, 2004 as U.S. Patent Application Publication No. 2004/0056211, all commonly assigned to Applied Materials, Inc., and all of which are incorporated herein by reference in their entireties. The Lavacoat™ process forms electron beam textured features 65, which can include a plurality of depressions 66 as well as protuberances 67, to which process deposits generated during processing can adhere.

The Lavacoat™ textured surface 22 can be formed by generating an electromagnetic energy beam 40, such as an electron beam 40, and directing the beam onto the surface 22 of the component 10. While the electromagnetic energy beam is preferably an electron beam, it can also comprise protons, neutrons and X-rays and the like. The beam 40 is typically focused on a region of the surface 22 for a period of time, during which time the beam 40 interacts with the surface 22 to form the textured features 65 on the surface 22. It is believed that the beam 40 forms the features 65 by rapidly heating the region of the surface 22, in some cases to a melting temperature of the surface material. The rapid heating causes some of the surface material to be ejected outwards, which forms depressions 66 in the regions the material was ejected from, and can form protuberances 67 in areas where the ejected material re-deposits. After the desired features in the region are formed, the beam 40 is scanned to a different region of the component surface 22 to form features in the new region. In one version, the surface 22 of the component 10 is scanned with the electron beam 40 after the concentric grooves 64 have been formed in the surface 22 of the component structure 11, and a desired density of textured depressions 66 can be formed between adjacent grooves 64. In another version, the grooves 64 may be formed in the surface 22 after forming the electron beam textured depressions 66.

The electromagnetic energy beam 40 can be scanned across the surface 22 to form a desired pattern of textured features 65 on the surface 22, such as a honeycomb-like structure of depressions 66 and protuberances 67. The features 55 formed by this method are typically macroscopically sized. For example, the depressions d can have a depth d as measured from a base level 68 of the surface 22 of from about 25 micrometers (0.001 inches) to about 1524 micrometers (0.060 inches). A surface diameter w of the depressions 66 may be from about 127 micrometers (0.005 inches) to about 2540 micrometers (0.1 inches), and even from about 203 micrometers (0.008 inches) to about 2261 micrometers (0.089 inches). The protuberances 67 can comprise a height h above the base level 68 of from about 51 micrometers (0.002 inches) to about 1524 micrometers (0.060 inches), and even from about 51 micrometers (0.002 inches) to about 1168 micrometers (0.046 inches.) The Lavacoat™ textured surface 22 can have an overall surface roughness average of from about 2500 microinches (64 micrometers) to about 4000 microinches (102 micrometers), the roughness average of the surface 22 being defined as the mean of the absolute values of the displacements from the mean line of the features along the surface 22. The textured surface 22 can also be further roughened after scanning with the electromagnetic energy beam 40 to provide different levels of texture on the surface 22, as described for example in the patent applications to Popiolkowski et al. and West et al. that are incorporated by reference above. For example, the surface 22 can be bead blasted by propelling blasting beads towards the surface 22 with pressurized gas, or can be chemically roughened, to form a relatively fine texture overlying the macroscopically sized features 65 on the surface 22. The electron beam textured surface 22 improves the adhesion of process deposits to reduce contamination of the processed substrates 104.

In one version, the component 10 having the textured surface 22, such as the retaining clamp 20 comprising the knurled surface 22, is a part of a process chamber 106 that is capable of performing one or more of an aluminum deposition process and aluminum re-flow process, an embodiment of which is shown in FIG. 3. A suitable chamber may comprise a PVD AI chamber, an embodiment of which is also described in U.S. Pat. No. 6,660,135 to Yu et al, issued Dec. 9, 2003, and commonly assigned to Applied Materials, which is herein incorporated by reference in its entirety. The chamber shown in FIG. 3 comprises enclosure walls 118, which may comprise a ceiling 119, sidewalls 121, and a bottom wall 122 that enclose a process zone 113, and may also include a chamber shield 123 adapted to shield a wall of the chamber from the energized process gas. The chamber shield 123 can include one or more of an upper shield 123a adapted to protect an upper portion of the chamber 106, such as upper portions of chamber sidewalls 121 and ceiling 119, and a lower shield 123b adapted to protect a lower portion of the chamber 106, such as lower portions of chamber sidewalls 121 and the bottom wall 122. A sputtering gas can be introduced into the chamber 106 through a gas supply 130 that includes a sputtering gas source 131, and a gas distributor 132. In the version shown in FIG. 3, the gas distributor 132 comprises one or more conduits 133 having one or more gas flow valves 134a,b and one or more gas outlets 135 around a periphery of the substrate 104. The sputtering gas can comprise, for example, an inert gas such as argon. A substrate support 100 comprises a substrate receiving surface 180 to receive a substrate 104, and a process kit 139 comprising, for example, the retaining clamp 20, can be provided on the support 100 to hold or clamp the substrate 104 onto the surface 180. Other exemplary process chambers 106 may have process kits 139 comprising components such as deposition rings and cover rings. An electrode in the support 100 below the substrate 104 may be powered by an electrode power supply to electrostatically hold the substrate on the support 100 during processing. Spent process gas and process byproducts are exhausted from the chamber 106 through an exhaust 120 which may include an exhaust conduit 127 that receives spent process gas from the process zone 113, a throttle valve 129 to control the pressure of process gas in the chamber 106, and one or more exhaust pumps 140.

The chamber 106 further comprises a sputtering target 124 facing a surface 105 of the substrate 104, and having material to be sputtered onto the substrate 104, such as for example aluminum. The target 124 can be electrically isolated from the chamber 106 by an annular insulator ring 136, and is connected to a power supply 192. The sputtering chamber 106 can also have a shield (not shown) to protect a wall 118 of the chamber 106 from sputtered material. A gas energizer 116, which can include one or more of the power supply 192, target 124, chamber walls 118 and support 100, is capable of energizing the sputtering gas to sputter material from the target 124. The power supply 192 applies a bias voltage to the target 124 with respect to another portion of the chamber 106, such as the chamber sidewall 118. The electric field generated in the chamber 106 from the applied voltage energizes the sputtering gas to form a plasma that energetically impinges upon and bombards the target 124 to sputter material off the target 124 and onto the substrate 104. The support 100 may comprise an electrode that operates as part of the gas energizer 116 by energizing and accelerating ionized material sputtered from the target 124 towards the substrate 104.

To process a substrate 104, the process chamber 106 is evacuated and maintained at a predetermined sub-atmospheric pressure. The substrate 104 is then provided on the support 100 by a substrate transport, such as for example a robot arm and lift pin assembly. The substrate 104 may be held on the support 100 by applying a voltage to an electrode in the support 100 via an electrode power supply. The gas supply 130 provides a process gas to the chamber 106 and the gas energizer 116 energizes the sputtering gas to sputter the target 124 and deposit material on the substrate 104. Effluent generated during the chamber process is exhausted from the chamber 106 by the exhaust 120.

The chamber 106 can be controlled by a controller 194 that comprises program code having instruction sets to operate components of the chamber 106 to process substrates 104 in the chamber 106. For example, the controller 194 can comprise a substrate positioning instruction set to operate one or more of the substrate support 100 and robot arm and lift pins 152 to position a substrate 104 in the chamber 106; a gas flow control instruction set to operate the gas supply 130 and flow control valves to set a flow of gas to the chamber 106; a gas pressure control instruction set to operate the exhaust 120 and throttle valve to maintain a pressure in the chamber 106; a gas energizer control instruction set to operate the gas energizer 116 to set a gas energizing power level; a temperature control instruction set to control temperatures in the chamber 106, such as a temperature of the substrate 104; and a process monitoring instruction set to monitor the process in the chamber 106.

Although exemplary embodiments of the present invention are shown and described, those of ordinary skill in the art may devise other embodiments which incorporate the present invention, and which are also within the scope of the present invention. For example, other retaining clamp configurations other than the exemplary ones described herein can also be provided. Also, the retaining clamp may be a part of process chambers other than those described. Also, other chamber components besides those specifically described could be textured according to one of the above-described methods. Furthermore, relative or positional terms shown with respect to the exemplary embodiments are interchangeable. Therefore, the appended claims should not be limited to the descriptions of the preferred versions, materials, or spatial arrangements described herein to illustrate the invention.

1. A substrate processing chamber component capable of being exposed to an energized gas in a process chamber, the component comprising:
(a) a component structure; and
(b) a surface on the component structure, the surface comprising (i) a plurality of concentric grooves that are radially spaced apart across the surface, and (ii) electron beam textured depressions formed between adjacent grooves on the surface,
whereby process residues adhere to the surface to reduce the contamination of processed substrates.

2. A component according to claim 1 wherein adjacent concentric grooves are separated by a distance that is at least twice as large as a distance between adjacent electron beam textured depressions.

3. A component according to claim 2 wherein a distance between adjacent concentric grooves is from about 5 millimeters to about 7 millimeters, and a distance between adjacent electron beam textured depressions between the grooves is from about 1 millimeter to about 3 millimeters.

4. A component according to claim 2 wherein a depth of the concentric grooves in the surface is from about 3 millimeters to about 8 millimeters, and a depth of the electron beam textured depressions in the surface is from about 25 micrometers to about 1524 micrometers.

5. A component according to claim 1 comprising surface regions between adjacent grooves having concave surface profiles.

6. A component according to claim 1, the component comprising at least a portion of a substrate support, chamber enclosure wall, gas supply, gas energizer, and gas exhaust.

7. A substrate processing chamber comprising the component of claim 1, the chamber comprising a substrate support, a process gas supply, a gas energizer, and a gas exhaust.

8. A method of manufacturing a component for a substrate processing chamber, the method comprising:
(a) providing a component structure having a surface;
(b) machining a plurality of concentric grooves into the surface, the concentric grooves being radially spaced apart on the surface; and
(c) scanning an electron beam across the surface to form a plurality of electron beam textured depressions between adjacent concentric grooves.

9. A method according to claim 8 wherein (b) comprises machining a plurality of concentric grooves having a distance between adjacent grooves that is at least twice a distance between adjacent electron beam textured depressions formed in (c).

10. A method according to claim 8 wherein (b) comprises machining grooves having a depth of from about 3 millimeters to about 8 millimeters, and wherein (c) comprises scanning the electron beam to form electron beam textured depressions having a depth of from about 25 micrometers to about 1524 micrometers.
